(19) United States
(12) Patent Application Publication
(10) Pub. No.: US 2021/0013867 A1
(43) Pub. Date: Jan. 14, 2021

(54) ACOUSTIC WAVE DEVICE

(71) Applicant: Murata Manufacturing Co., Ltd., Nagaokakyo-shi (JP)

(72) Inventors: Kazunori INOUE, Nagaokakyo-shi (JP); Shintaro OTSUKA, Nagaokakyo-shi (JP); Koichiro KAWASAKI, Nagaokakyo-shi (JP); Hidefumi NAKANISHI, Nagaokakyo-shi (JP); Masakazu ATARASHI, Nagaokakyo-shi (JP); Masahiro FUKUSHIMA, Nagaokakyo-shi (JP); Tsutomu MUROTANI, Nagaokakyo-shi (JP)

(21) Appl. No.: 16/919,175

(22) Filed: Jul. 2, 2020

(30) Foreign Application Priority Data
Jul. 10, 2019 (JP) 2019-128662

(51) Int. Cl. H03H 9/10; H03H 9/05

(52) U.S. Cl. CPC H03H 9/1092; H03H 9/059

(57) ABSTRACT

An acoustic wave device includes a functional electrode provided on a first main surface of a substrate, and a support provided on the substrate and surrounding a portion where the functional electrode is provided. A cover closes an opening of the support. The cover includes a resin layer and a metal layer that is integrated with the resin layer. The metal layer includes a first metal layer and a second metal layer, the first metal layer having a larger planar area than the second metal layer. The Young's modulus of the metal defining the second metal layer is higher than the Young's modulus of the metal defining the first metal layer. In a plan view, the first metal layer covers a hollow portion from above and the second metal layer discontinuously covers the hollow portion from above.

### CROSS REFERENCE TO RELATED APPLICATIONS

This application claims the benefit of priority to Japanese Patent Application No. 2019-128662 filed on Jul. 10, 2019. The entire contents of this application are hereby incorporated herein by reference.

### BACKGROUND OF THE INVENTION

### 1. Field of the Invention

The present invention relates to an acoustic wave device having a hollow structure in which a support and a cover are stacked on a substrate.

### 2. Description of the Related Art

To date, various acoustic wave devices having a wafer level package (WLP) structure have been proposed. For example, in Japanese Unexamined Patent Application Publication No. 2018-098816, a frame-shaped support is provided on a piezoelectric substrate. A cover is attached so as to close the opening of the frame-shaped support. Thus, a hollow portion is provided. The cover includes a composite resin layer and a metal layer stacked on the composite resin layer. The strength of the cover is increased by providing the metal layer. Japanese Unexamined Patent Application Publication No. 2018-098816 describes that the metal layer preferably has a structure consisting of a first conductor layer made of Ni, Cr, or Ti and a second conductor layer made of Cu stacked one on top of the other.

In Japanese Patent No. 4299126, a cover includes a resin layer and a metal layer stacked on the resin layer. In Japanese Patent No. 4299126, the metal layer consists of a metal film made of Cu, Al, Ni, Ti, or Cr or an alloy with any of these metals as a main component, or a multilayer film consisting of any of these metals. In Japanese Patent No. 4299126, a through hole is provided in the cover using a laser. This through hole forms a portion where a terminal electrode will be formed.

In the acoustic wave device disclosed in Japanese Unexamined Patent Application Publication No. 2018-098816, when the first conductor layer is made of Ni or Cr, the first conductor layer is hard and has a low coefficient of linear expansion. In this case, when exposed to a high temperature during the manufacturing process or during use, considerable thermal stress is generated between the metal layer and the resin layer, which has a high coefficient of thermal expansion. Consequently, there is a risk that the cover will become detached from the support.

In the acoustic wave device disclosed in Japanese Patent No. 4299126 as well, there is a risk of the same problem occurring when the metal layer is made of Ni, Cr, or the like.

### SUMMARY OF THE INVENTION

Preferred embodiments of the present invention provide acoustic waves device that each have a strong cover and in each of which the cover is unlikely to become detached due to thermal stress even during exposure to high temperatures when being manufactured or operated.

An acoustic wave device according to a preferred embodiment of the present invention includes a substrate including a first main surface and a second main surface that faces the first main surface and including a piezoelectric layer at the first main surface side thereof; a functional electrode that is provided on the piezoelectric layer; a support that is provided on the substrate and surrounds a portion where the functional electrode is provided; and a cover that closes an opening of the support. A hollow portion is defined by the substrate, the support, and the cover. The cover includes a resin layer and a metal layer that is integrated with the resin layer. The metal layer includes a first metal layer and a second metal layer, the first metal layer having a larger planar area than the second metal layer. A Young's modulus of a metal defining the second metal layer is higher than a Young's modulus of a metal defining the first metal layer. In a plan view, the first metal layer covers the hollow portion from above and the second metal layer discontinuously covers the hollow portion from above.

According to preferred embodiments of the present invention, acoustic wave devices are able to be provided that each have a strong cover and in each of which the cover is unlikely to become detached due to thermal stress even during exposure to high temperatures when being manufactured or operated.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a front sectional view of an acoustic wave device according to a first preferred embodiment of the present invention.

FIG. 2A is a plan view of a structure in which a frame is provided on a substrate included in the first preferred embodiment of the present invention, FIG. 2B is a plan view showing a structure in which a cover covers the frame, and FIG. 2C is a plan view showing a state in which a first layer of a metal layer of the cover is exposed.

FIG. 3 is a plan view showing a state in which first and second layers of the cover of the acoustic wave device of the first preferred embodiment of the present invention are exposed.

FIG. 4 is a plan view of the acoustic wave device of the first preferred embodiment of the present invention.

FIG. 5 is a front sectional view of an acoustic wave device of a second preferred embodiment of the present invention.

FIG. 6 is a plan view of an acoustic wave device of a third preferred embodiment of the present invention.

FIG. 7 is a plan view of an acoustic wave device of a fourth preferred embodiment of the present invention.

FIG. 8 is a plan view showing an acoustic wave device of a fifth preferred embodiment of the present invention and shows a state in which first and second layers are exposed.

FIG. 9 is a partial front sectional view showing an acoustic wave device of a sixth preferred embodiment of the present invention.

### DETAILED DESCRIPTION OF THE PREFERRED EMBODIMENTS

Hereafter, the present invention will be made clearer by describing preferred embodiments of the present invention with reference to the drawings.

The preferred embodiments described in the present specification are examples and portions, components, and elements of different preferred embodiments may be substituted for one another or combined with one another.

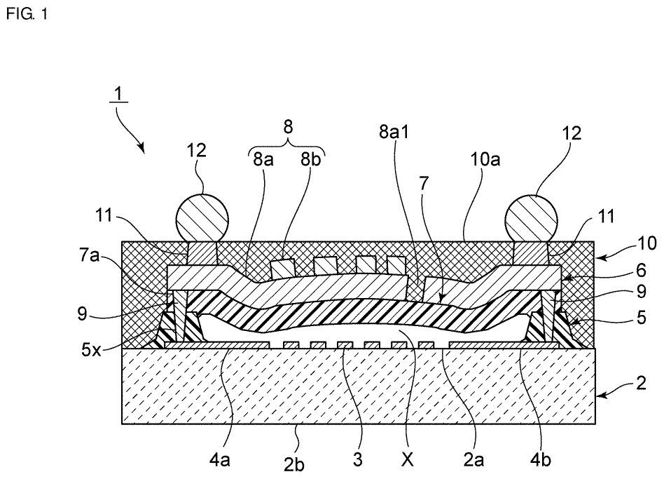

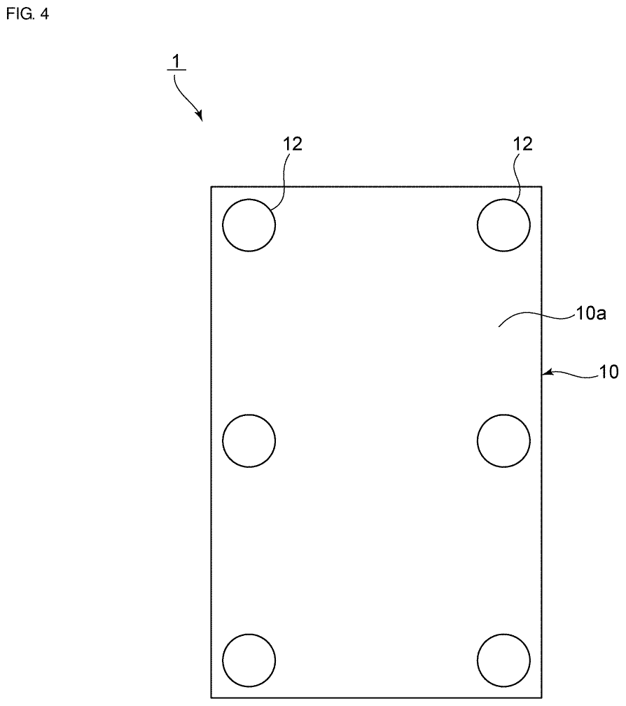

FIG. 1 is a front sectional view and FIG. 4 is a plan view of an acoustic wave device according to a first preferred embodiment of the present invention.

An acoustic wave device 1 includes a substrate 2. The substrate 2 includes first and second main surfaces 2a and 2b, which face each other. In the first preferred embodiment, the substrate 2 is preferably, for example, a piezoelectric substrate that is entirely a piezoelectric layer. However, the substrate 2 may have a structure in which a piezoelectric layer is provided on an insulating substrate. It is sufficient that the piezoelectric layer is provided at the first main surface 2a side of the substrate 2.

A functional electrode 3 is provided on the first main surface 2a. In the first preferred embodiment, the functional electrode 3 includes an interdigital transducer (IDT) electrode. Wiring electrodes 4a and 4b are electrically connected to the functional electrode 3.

A support 5 is provided on the first main surface 2a of the substrate 2. The support 5 is preferably made of a composite resin, for example, polyimide. The support 5 may be made of another insulating material.

The support 5 is substantially frame-shaped and surrounds the portion where the functional electrode 3 is provided.

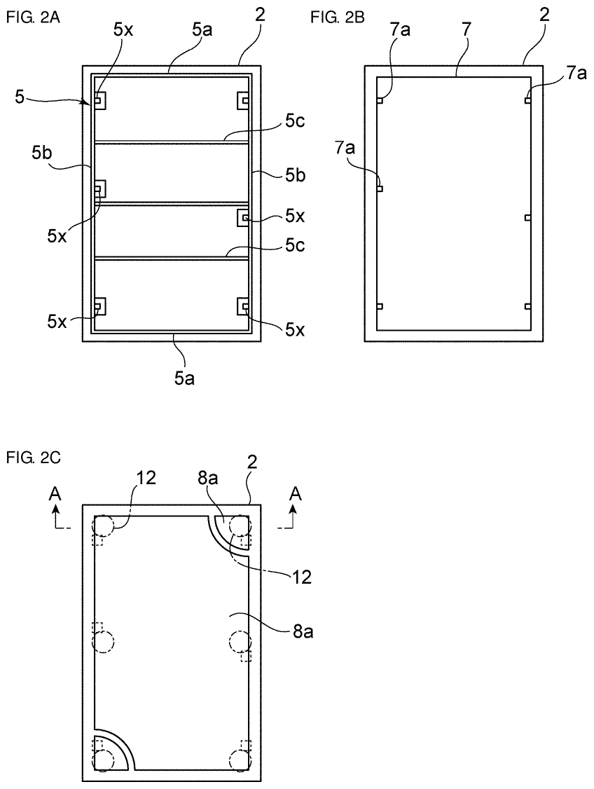

FIG. 2A is a plan view showing a structure in which the support 5 is provided on the first main surface 2a of the substrate 2. Here, the functional electrode 3 and the wiring electrodes 4a and 4b are not shown.

As shown in FIG. 2A, a rectangular or substantially rectangular frame-shaped support 5 is provided. The substrate 2 has a rectangular or substantially rectangular shape and has short sides and long sides in a plan view. The support 5 includes short side portions 5a and long side portions 5b. The short side portions 5a extend in a direction along the short sides of the substrate 2. The long side portions 5b extend in a direction along the long sides of the substrate 2. In addition, one or more partition walls 5c are provided to significantly increase mechanical strength, and the partition walls 5c connect the opposing long side portions 5b to each other.

As shown in FIGS. 1 and 2A, through holes 5x are provided in the support 5. The through holes 5x are included to provide terminal electrodes, which are described later.

As shown in FIG. 1, a cover 6 is fixed to an upper surface of the support 5 to close an opening of the support 5. Thus, a hollow portion X is provided. The hollow portion X is surrounded by the first main surface 2a of the substrate 2 and the support 5 and the cover 6.

The cover 6 includes a resin layer 7 and a metal layer 8. The resin layer 7 is made of a resin, for example, a polyimide, polyester, or epoxy resin. The resin layer 7 is fixed to the support 5 to close the opening of the support 5. The metal layer 8 is stacked on the resin layer 7. The metal layer 8 is included to increase the strength of the cover 6. The metal layer 8 includes a first metal layer 8a and a plurality of second metal layers 8b that are stacked on the first metal layer 8a. The first metal layer 8a has the same or substantially the same planar shape as the resin layer 7. More specifically, there are missing portions 8a1 in portions of the first metal layer 8a. The planar shape circumscribing the first metal layer 8a is identical or substantially identical to the planar shape circumscribing the resin layer 7.

On the other hand, the plurality of second metal layers 8b discontinuously cover the hollow portion X from above in a plan view, that is, the second metal layers 8b are discontinuously provided and located in portions of the region above the hollow portion X.

FIG. 2B is a plan view of a structure in which the cover 6 has been stacked and FIG. 2C is a plan view showing a state in which a second layer of the cover 6 has been removed and a first layer of the cover 6 is exposed.

FIG. 1 is a sectional view taken along line A-A in FIG. 2C.

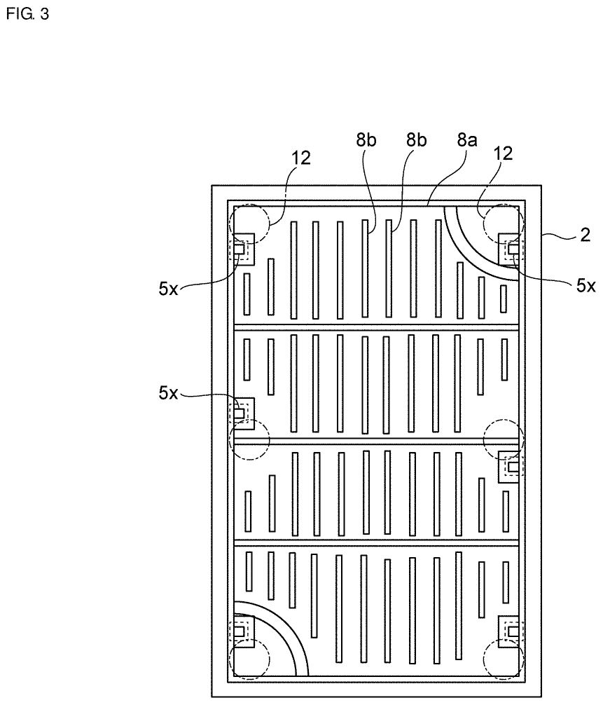

FIG. 3 is a plan view of a structure in which the first layer and the second layer are exposed. As is clear from FIG. 3, the exposed second metal layers 8b extend in the long side direction and are arrayed in the short side direction.

The Young's modulus of the metal defining the second metal layers 8b is higher than the Young's modulus of the metal defining the first metal layer 8a. Therefore, in the first preferred embodiment, the strength of the cover 6 is high due to the presence of the second metal layers 8b. On the other hand, the plurality of second metal layers 8b are discontinuously provided above the hollow portion X. Therefore, thermal stress caused by a difference in thermal expansion is able to be significantly reduced or prevented even during exposure to a high temperature, for example, during manufacture or use. In other words, the difference in thermal stress between the cover 6 and the resin layer 7, which is made of a resin, is able to be reduced. Therefore, it is unlikely that the cover 6 will become detached from the support 5.

The electrical conductivity of the metal defining the first metal layer 8a is preferably higher than the electrical conductivity of the metal defining the second metal layers 8b, for example. As a result, when the first metal layer 8a is used as a wiring line through which an electrical signal flows, loss is able to be reduced.

Returning to FIG. 1, through holes 7a are provided in the resin layer 7 of the cover 6 and connected to the through holes 5x of the support 5. The through holes 5x and the through holes 7a are able to be provided by radiating laser light from above, for example. Terminal electrodes 9 are provided inside the through holes 5x and 7a. The lower ends of the terminal electrodes 9 are bonded to the wiring electrodes 4a and 4b. The upper ends of the terminal electrodes 9 are bonded to the first metal layer 8a. The first metal layer 8a defines and functions as a wiring line through which a signal flows.

An exterior resin layer 10 covers the outside of the cover 6. Then, under bump metal layers 11 extend to an upper surface 10a of the exterior resin layer 10. Metal bumps 12 are provided on the under bump metal layers 11. The metal bumps 12 are made of a metal or an alloy, for example, solder or Au.

The metal defining the first metal layer 8a may be, for example, Cu or Au or an alloy including either of these metals as a main component. Cu is more preferable, for example, because Cu has excellent electrical conductivity and is low cost.

The metal defining the second metal layers 8b is not particularly limited as long as the Young's modulus of this metal is higher than that of the metal defining the first metal layer 8a. The metal defining the second metal layers 8b may be, for example, Ni, Cr, Pt, W, Ti, or Ta or an alloy having any of these metals as a main component.

The second metal layers 8b are preferably made of, for example, Ni. When Ni is used, magnetic force may be applied to fix the acoustic wave device 1 during mounting and temporary fixing.

When the first metal layer 8a is made of Cu and the second metal layers 8b are made of Ni, mechanical strength is able to be significantly increased by the second metal layers 8b. Furthermore, since the second metal layers 8b are discontinuously provided in a plan view, the difference between the thermal expansion coefficient of the metal layer 8 and the thermal expansion coefficient of the resin layer 7 is able to be reduced. Therefore, a situation in which the cover 6 becomes detached is able to be significantly reduced or prevented. In addition, since the first metal layer 8a has excellent electrical conductivity, loss is also able to be reduced.

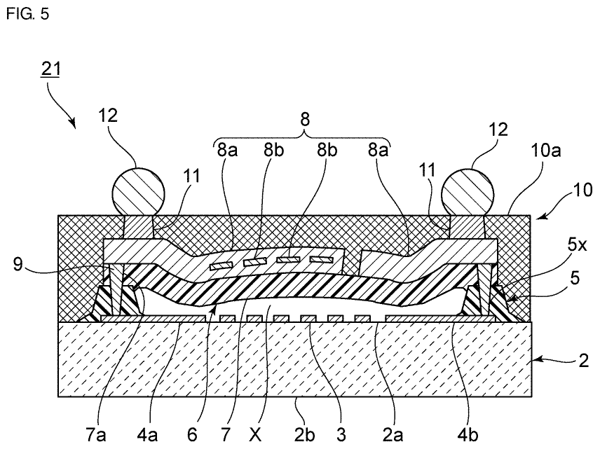

FIG. 5 is a front sectional view of an acoustic wave device according to a second preferred embodiment of the present invention. In an acoustic wave device 21 of the second preferred embodiment, the plurality of second metal layers 8b are buried inside the first metal layer 8a. The rest of the structure of the acoustic wave device 21 is identical or substantially identical to that of the acoustic wave device 1. Thus, the second metal layers 8b may be buried inside the first metal layer 8a to significantly increase the mechanical strength of the cover 6 by the second metal layers 8b. Furthermore, similar to the first preferred embodiment, detachment of the cover 6 from the support 5 due to a difference in thermal stress is able to be significantly reduced or prevented.

It is sufficient that the second metal layers 8b is discontinuously provided above the hollow portion X in a plan view. The specific structure in which the second metal layers 8b are discontinuously provided is not particularly limited. Furthermore, a single second metal layer 8b may be provided. It is sufficient that discontinuous portions in a cross section in a predetermined direction are provided in the single second metal layer 8b.

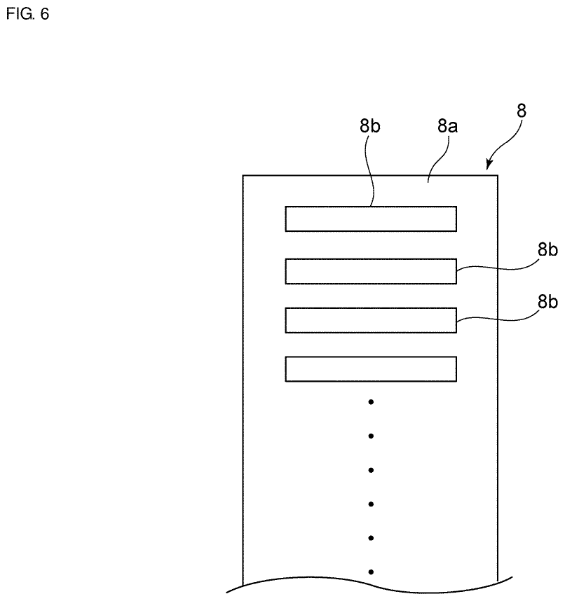

FIG. 6 is a plan view of an acoustic wave device according to a third preferred embodiment of the present invention. In the third preferred embodiment, the hollow portion X is rectangular or substantially rectangular in a plan view. In other words, the hollow portion X has long sides and short sides in a plan view. A plurality of second metal layers 8b have a substantially elongated strip shape. That is, the second metal layers 8b have a longitudinal direction. The longitudinal direction extends along a short-side direction of the hollow portion X.

The difference between the coefficients of linear expansion of the metal layer 8 and the resin layer 7 is larger in the long-side direction of the hollow portion X than in the short-side direction of the hollow portion X. Therefore, the plurality of second metal layers 8b preferably extend, for example, in the short-side direction of the hollow portion X and be arrayed in the long-side direction of the hollow portion X. Thus, detachment of the cover 6 due to a difference in thermal stress is able to be further significantly reduced or prevented.

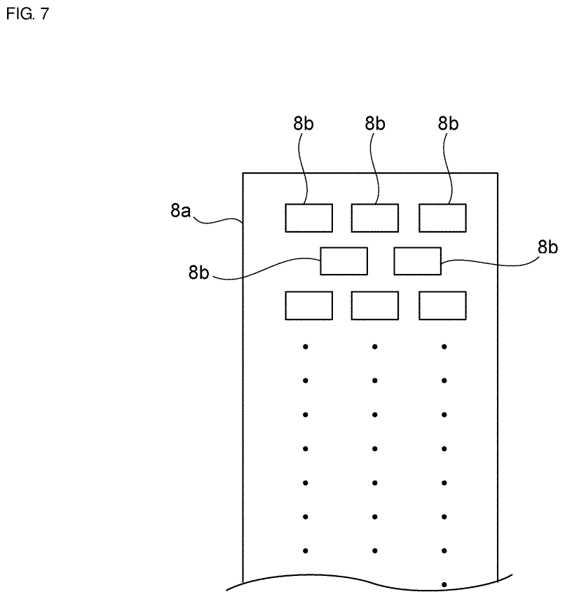

FIG. 7 is a plan view of an acoustic wave device according to a fourth preferred embodiment of the present invention. In the fourth preferred embodiment, a plurality of second metal layers 8b are staggered from one another in a plan view. Thus, the plurality of second metal layers 8b may be staggered or may be provided in a matrix pattern, and the locations of the second metal layers 8b are not particularly limited.

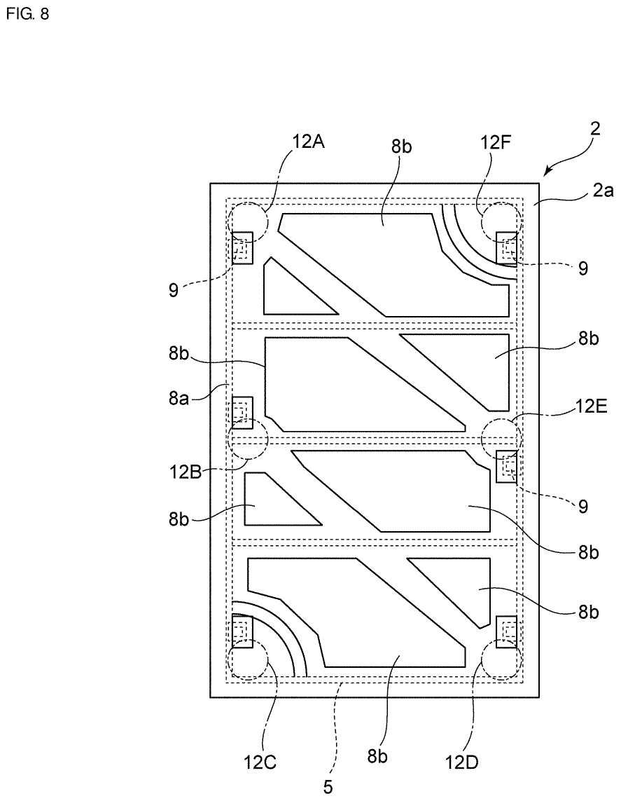

FIG. 8 is a plan view of an acoustic wave device of a fifth preferred embodiment of the present invention showing a state in which first and second metal layers are exposed. In this acoustic wave device, the plurality of second metal layers 8b are discontinuously provided on the first metal layer 8a. In FIG. 8, one-dot chain line circles show the positions where metal bumps 12A to 12F are bonded. Furthermore, the dashed lines show the portions where the underlying terminal electrodes are located.

In the acoustic wave device, the second metal layers 8b are separated from the terminal electrodes 9. Furthermore, the second metal layers 8b are also separated from the metal bumps 12A to 12F. Therefore, for example, the second metal layers 8b are not provided in a straight-line-shaped region connecting the metal bump 12A and the metal bump 12E, for example. Therefore, the electrical conductivity of a line connecting the metal bump 12A and the metal bump 12E is high. As a result, loss is reduced. Thus, the second metal layers 8b preferably avoid portions where lines along which signals flow are provided. Therefore, the second metal layers 8b are preferably separated from the terminal electrodes 9.

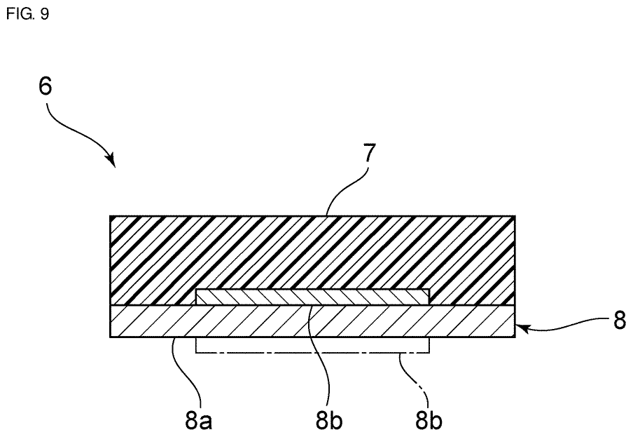

FIG. 9 is a partial front sectional view showing an acoustic wave device of a sixth preferred embodiment of the present invention. In the sixth preferred embodiment, the second metal layers 8b are stacked on a portion of one surface of the first metal layer 8a in the cover 6. The resin layer 7 is stacked on the metal layer 8. Thus, the resin layer 7 is stacked on the upper surface of the metal layer 8, i.e., on the surface of the metal layer 8 on the opposite side from the hollow portion. Furthermore, the second metal layers 8b may be provided on the lower surface side of the first metal layer 8a.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a substrate including a first main surface, a second main surface that faces the first main surface, and a piezoelectric layer at the first main surface side thereof;
a functional electrode provided on the piezoelectric layer;
a support provided on the substrate and surrounding a portion where the functional electrode is provided; and
a cover that closes an opening of the support; wherein
a hollow portion is defined by the substrate, the support, and the cover;
the cover includes a resin layer and a metal layer that is integrated with the resin layer;
the metal layer includes a first metal layer and a second metal layer, the first metal layer having a larger planar area than the second metal layer;
a Young's modulus of a metal defining the second metal layer is higher than a Young's modulus of a metal defining the first metal layer;
in a plan view, the first metal layer covers the hollow portion from above; and
the second metal layer discontinuously covers the hollow portion from above.

2. The acoustic wave device according to claim 1, wherein the first metal layer is made of Cu and the second metal layer is made of Ni.

3. The acoustic wave device according to claim 1, wherein the hollow portion has a rectangular or substantially rectangular shape having short sides and long sides in a plan view, and the second metal layer has a shape that extends in the short-side direction.

4. The acoustic wave device according to claim 1, further comprising:
a terminal electrode penetrating through the support and the cover; wherein
the terminal electrode is electrically connected to the functional electrode.

5. The acoustic wave device according to claim 4, wherein the second metal layer is separated from the terminal electrode in a plan view.

6. The acoustic wave device according to claim 1, wherein the second metal layer includes a plurality of second metal layers.

7. The acoustic wave device according to claim 1, wherein the second metal layer is stacked on at least one main surface of the first metal layer.

8. The acoustic wave device according to claim 1, wherein the second metal layer is buried inside the resin layer.

9. The acoustic wave device according to claim 1, wherein the functional electrode is an interdigital transducer electrode.

10. The acoustic wave device according to claim 1, wherein at least one wiring electrode is provided on the first main surface of the substrate.

11. The acoustic wave device according to claim 1, wherein the support includes an insulating material.

12. The acoustic wave device according to claim 1, wherein the support has a rectangular or substantially rectangular frame shape in plan view.

13. The acoustic wave device according to claim 1, wherein at least one through hole is provided in the support.

14. The acoustic wave device according to claim 1, wherein an electrical conductivity of the first metal layer is higher than an electrical conductivity of the second metal layer.

15. The acoustic wave device according to claim 4, wherein the terminal electrode is electrically connected to the first metal layer.
